(19) United States
(12) Patent Application Publication
(10) Pub. No.: US 2022/0418047 A1
(43) Pub. Date: Dec. 29, 2022

(54) THIN-FILM HEATER, METHOD OF PRODUCING THIN-FILM HEATER, AND THERMOSTATIC OVEN PIEZOELECTRIC OSCILLATOR

(71) Applicant: DAISHINKU CORPORATION, Kakogawa-shi, Hyogo (JP)

(72) Inventors: Minoru IIZUKA, Kakogawa-shi (JP); Takuya KOJO, Kakogawa-shi (JP); Yoshinari MORIMOTO, Kakogawa-shi (JP)

(73) Assignee: DAISHINKU CORPORATION, Kakogawa-shi, Hyogo (JP)

(21) Appl. No.: 17/774,877

(22) PCT Filed: Feb. 19, 2021
(86) PCT No.: PCT/JP2021/006419

§ 371 Date: May 6, 2022

(30) Foreign Application Priority Data
Mar. 3, 2020 (JP) 2020-036072

(51) Int. Cl. H05B 3/34; H05B 3/12; H03B 5/32

(52) U.S. Cl. CPC H05B 3/34; H05B 3/12; H03B 5/32

(57) ABSTRACT

A thin-film heater according to one or more embodiments may include an insulated substrate and metal wiring patterned thereon to extend between both terminals of the metal wiring. The metal wiring has a resistance of 10Ω or less between the terminals. The metal wiring includes a heat-generating layer made of a material that recrystallizes at a temperature of 200° C. or lower.

### TECHNICAL FIELD

The present invention relates to a thin-film heater, a method of producing the thin-film heater, and an oven-controlled piezoelectric oscillator using the thin-film heater.

### BACKGROUND ART

For small devices such as oven-controlled piezoelectric oscillators (for example, Oven-Controlled Xtal (crystal) Oscillators, hereinafter referred to as “OCXO”, including temperature-controlled crystal oscillators) that require temperature adjustment, small resistors and high-resistant metal plates have served as heaters (PTL 1). Unfortunately, these small resistors and high-resistant metal plates cannot generate heat in a stable manner and cannot ensure high-precision temperature adjustment. High-precision temperature adjustment by these conventional heaters is further hampered by a low degree of freedom in heater shape, which often complicates arrangement of the heaters close to a point where temperature adjustment is required in the device.

### CITATION LIST

### Patent Literature

PTL 1: JP 2012-205093 A

### SUMMARY OF INVENTION

### Technical Problem

The present inventors have studied to use a thin-film heater as a temperature adjustment heater for an OCXO. The thin-film heater is composed of an insulated substrate and a metal film (metal wiring) patterned thereon. Since an OCXO is a small device, application of the thin-film heater to the OCXO necessitates an ultrasmall (and ultralow-power) thin-film heater.

A common method of producing an ultrasmall thin-film heater includes deposition of a metal film on an insulated substrate by sputtering, resistive thermal evaporation or the like, followed by precise patterning of the deposited metal film by photolithography or the like. However, the resulting ultrasmall and ultralow-power thin-film heater is still unsatisfactory because microscopic structural defects in the metal film cause local destabilization of a resistance and lead to uneven heat generation.

The present invention is made in view of these problems and has following objects: firstly, to provide a thin-film heater that generates heat more uniformly, and a method of producing the thin-film heater; and secondly, to provide an oven-controlled piezoelectric oscillator that uses this thin-film heater and that conducts high-precision temperature adjustment.

### Solution to Problem

As the first aspect of the present invention, a thin-film heater is provided to solve the above-mentioned problems. This thin-film heater includes an insulated substrate and metal wiring patterned thereon to extend between both terminals of the metal wiring, and is characterized by following features. The metal wiring has a resistance of 10Ω or less between the terminals. The metal wiring includes either a heat-generating layer made of a material that recrystallizes at a temperature of 200° C. or lower or a heat-generating layer formed as a recrystallized film.

According to this configuration, recrystallization caused to occur in the heat-generating layer achieves microscopic evenness in the composition and texture of the heat-generating layer and eventually ensures uniform heat generation throughout the heater.

In the above thin-film heater, the material for the heat-generating layer may be selected from the group consisting of gold (Au), aluminum (Al), silver (Ag), and copper (Cu).

In the above thin-film heater, the insulated substrate may be quartz or glass, and the metal wiring may include an underlayer formed between the insulated substrate and the heat-generating layer.

According to this configuration, the underlayer interposed between the insulated substrate and the heat-generating layer can enhance adhesion property of the heat-generating layer to the insulated substrate.

In the above thin-film heater, the heat-generating layer may have a film thickness of 30 nm or more, and the underlayer may have a film thickness of 10 nm or less.

As the second aspect of the present invention, a method of producing a thin-film heater is provided to solve the above-mentioned problems. This is a method of producing a thin-film heater that has an insulated substrate and metal wiring patterned thereon to extend between both terminals of the metal wiring, wherein the metal wiring includes a heat-generating layer. The method is characterized by forming the heat-generating layer through a deposition step and a patterning step as specified below. The deposition step includes using a material that recrystallizes at a temperature of 200° C. or lower, preheating the insulated substrate to 200° C. or higher, and depositing a metal film on the preheated insulated substrate by a vacuum vapor deposition method. The patterning step includes patterning, by etching, the metal film deposited in the deposition step.

As the third aspect of the present invention, an oven-controlled piezoelectric oscillator is provided to solve the above-mentioned problems. This oven-controlled piezoelectric oscillator includes a heater, a resonator, an oscillator IC combined with the resonator to configure an oscillator, and a heater IC for controlling the heater, and is characterized in that the heater at least includes one or more thin-film heaters mentioned above.

This configuration can provide an oven-controlled piezoelectric oscillator that conducts high-precision temperature adjustment, by using one or more thin-film heaters that ensure uniform heat generation throughout each heater.

In the above oven-controlled piezoelectric oscillator, the heater may include two of the one or more thin-film heaters. The oven-controlled piezoelectric oscillator may further include a core in which the resonator, the oscillator IC, and the heater IC are arranged in a temperature adjustment space defined between the two thin-film heaters, and the core may be hermetically encapsulated in an insulation package.

In the above oven-controlled piezoelectric oscillator, the oven-controlled piezoelectric oscillator may further include a core in which the heater IC, the resonator, the oscillator IC, and the thin-film heater are stacked on a flat plate-like core substrate sequentially from a side of the core substrate, and the core may be hermetically encapsulated in an insulation package.

### Advantageous Effects of Invention

The thin-film heater and the method of producing the thin-film heater according to the present invention provide the metal wiring of the thin-film heater with the heat-generating layer made of a recrystallized metal film, and thereby achieve an advantageous effect of ensuring uniform heat generation throughout the heater. The oven-controlled piezoelectric oscillator according to the present invention uses the one or more thin-film heaters that ensure uniform heat generation throughout each heater, and thereby achieves an advantageous effect of ensuring high-precision temperature adjustment.

### BRIEF DESCRIPTION OF DRAWINGS

FIG. 1 is a plan view showing a configuration example of a thin-film heater, according to an embodiment of the present invention.

FIG. 2 is a partial cross-sectional view of the configuration example of the thin-film heater, according to the embodiment of the present invention.

FIGS. 3(a)-3(c) are plan views showing modified examples of metal wiring patterns in the thin-film heater.

FIG. 4 is a cross-sectional view showing a structural example of a core of an OCXO using the thin-film heaters.

FIG. 5 is a plan view showing the structural example of the core of the OCXO using the thin-film heaters.

FIG. 6 is a cross-sectional view of the OCXO, with the core shown in FIGS. 4 and 5 on-board.

FIG. 7 is a cross-sectional view showing a modified example of a core of an OCXO using the thin-film heater.

FIG. 8 is a cross-sectional view of an OCXO, with the core shown in FIG. 7 on-board.

FIG. 9 is a cross-sectional view of another example of an OCXO, with the core shown in FIG. 7 on-board.

### DESCRIPTION OF EMBODIMENTS

### Embodiment 1

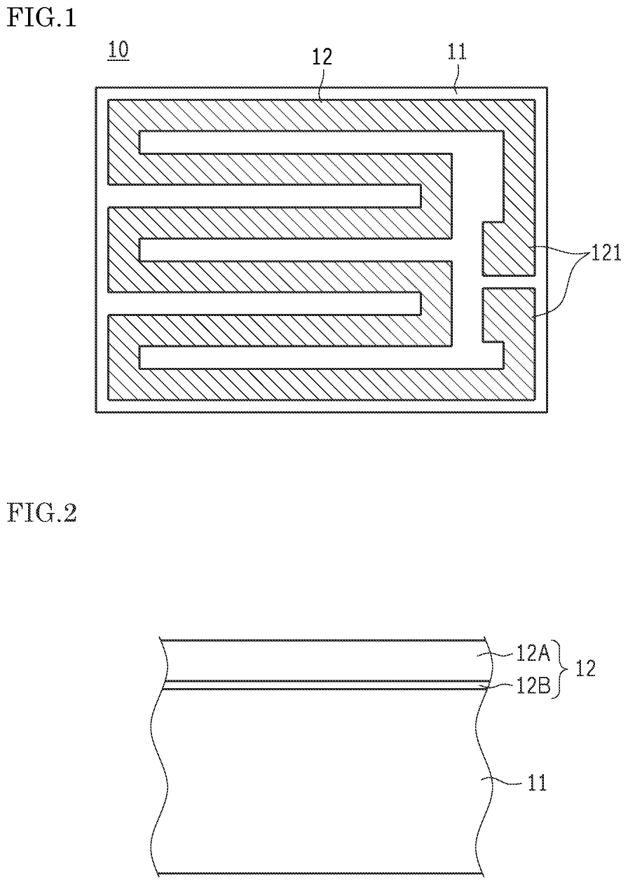

Embodiments of the present invention are hereinafter described in detail, with reference to the drawings. The description starts with a configuration and a production method of a thin-film heater according to the present embodiment. A configuration example of a thin-film heater 10 is shown by a plan view of FIG. 1 and a partial cross-sectional view of FIG. 2.

As shown in FIGS. 1 and 2, the thin-film heater 10 is composed of an insulated substrate 11 and metal wiring 12 patterned thereon. Electrode terminals 121 are provided at both ends of the metal wiring 12. The metal wiring 12 generates Joule heat when an electric current passes between these terminals. The metal wiring 12 at least includes a heat-generating layer 12A, but may also include an underlayer 12B between the insulated substrate 11 and the heat-generating layer 12A.

The thin-film heater 10 is meant for application to an OCXO that is a small device, and is used to keep an internal temperature of the OCXO at a given temperature (e.g., 90° C.). The thin-film heater 10 in this case needs to be not only ultrasmall in size but also ultralow-power in output. For example, the insulated substrate 11 of the thin-film heater 10 has a size of 5 mm×5 mm or smaller, and the resistance between the terminals of the metal wiring 12 is 10Ω or smaller (preferably 9±1Ω) to provide a low-power heater.

For production of the ultrasmall and ultralow-power thin-film heater 10, it is necessary to form the metal wiring 12 by depositing a metal film by a vacuum vapor deposition method such as sputtering or resistive thermal evaporation, and then by precisely patterning the deposited metal film by etching (photolithography, etc.). In this case, however, microscopic compositional variations and minute structural defects may occur during the deposition of the metal film by the vacuum vapor deposition method, and may cause uneven heating of the thin-film heater 10. Uneven heating of the thin-film heater 10 naturally complicates high-precision temperature adjustment in the OCXO.

In order to ensure uniform heating by the thin-film heater 10 according to the present embodiment, a material for the heat-generating layer 12A in the metal wiring 12 is specified to a material having a low recrystallization temperature. Specifically, the heat-generating layer 12A is made of a material that recrystallizes at a temperature of 200° C. or lower, including gold (Au), aluminum (Al), silver (Ag), copper (Cu), etc. The most preferable material for the heat-generating layer 12A is gold (Au), particularly in terms of corrosion resistance and the like.

Usually, a material having a low recrystallization temperature has a low melting point as well. Since a thin-film heater is meant to generate heat, a generally preferable material for its metal wiring is a high-melting-point material. Nevertheless, the metal wiring made of a high-melting-point material tends to develop microscopic compositional variations and minute structural defects during the deposition process. On the other hand, the thin-film heater 10 according to the present embodiment that is meant for use in an OCXO does not need to generate a large amount of heat, but rather needs to reduce the amount of heat generation. For this reason, the thin-film heater 10 can use a low-melting-point material without problem.

Further in the thin-film heater 10 that is meant for application to an OCXO, the insulated substrate 11 is preferably made of quartz or glass. When the insulated substrate 11 is made of quartz or glass, the metal wiring 12 is preferably provided with an underlayer 12B so as to enhance adhesion property of the heat-generating layer 12A to the insulated substrate 11. Materials for the underlayer 12B include titanium (Ti), chromium (Cr), molybdenum (Mo), tungsten (W), etc. A desirable material for the underlayer 12B has low diffusivity into the metal used for the heat-generating layer 12A and keeps adhesion property to the insulated substrate 11. When the heat-generating layer 12A is made of Au, the underlayer 12B is preferably made of Ti or W.

Strictly speaking, in the case where the metal wiring 12 includes the heat-generating layer 12A and the underlayer 12B, the thin-film heater 10 generates heat not only in the heat-generating layer 12A but also in the underlayer 12B. To enable more uniform heat generation in the thin-film heater 10, it is desirable that heat should be generated less in the underlayer 12B and as much as possible in the heat-generating layer 12A. In other words, it is desirable that the film thickness of the underlayer 12B should be sufficiently smaller than that of the heat-generating layer 12A. Specifically, a preferable film thickness of the underlayer 12B is 10 nm or less. On the other hand, the film thickness of the heat-generating layer 12A is determined by a resistance required in the thin-film heater 10 and by pattern size restrictions. The thus determined film thickness of the heat-generating layer 12A is generally about 300 nm, but the heat-generating layer 12A in the form of a completely continuous film needs a film thickness of about 30 nm. Accordingly, a preferable film thickness of the heat-generating layer 12A is 30 nm or more.

The method of producing the thin-film heater 10 according to the present embodiment forms the metal wiring 12 on the insulated substrate 11 by patterning. The production method includes deposition of a metal film by a vacuum vapor deposition method (deposition step) and precise patterning of the deposited metal film by etching (patterning step). In the case where the metal wiring 12 includes the heat-generating layer 12A and the underlayer 12B, each of the heat-generating layer 12A and the underlayer 12B is independently formed through the deposition step and the patterning step.

As mentioned above, the heat-generating layer 12A serving to generate most of the heat for the thin-film heater 10 is made of the material that recrystallizes at a temperature of 200° C. or lower (preferably Au). This is because the heat-generating layer 12A is formed as a recrystallized film in the thin-film heater 10. The recrystallized heat-generating layer 12A achieves microscopic evenness in the composition and texture of the metal film, and ensures uniform heat generation throughout the heater. Uniform heat generation in the heat-generating layer 12A leads to uniform heat generation in the thin-film heater 10, so that an OCXO using the thin-film heater 10 can conduct high-precision temperature adjustment. Occurrence or non-occurrence of recrystallization in the heat-generating layer 12A can be checked, for example, by X-RD (X-ray diffraction) or the like.

Preferably, the recrystallization in the heat-generating layer 12A is caused to occur during the metal film deposition step. To cause the recrystallization of the metal film, the metal film is heated during the deposition step to 200° C. or higher (namely, at least the recrystallization temperature of a metal material for the heat-generating layer 12). Specifically, the deposition step of depositing the metal film by a vacuum vapor deposition method is conducted on the insulated substrate 11 preheated to 200° C. or higher, to cause the recrystallization of the metal film.

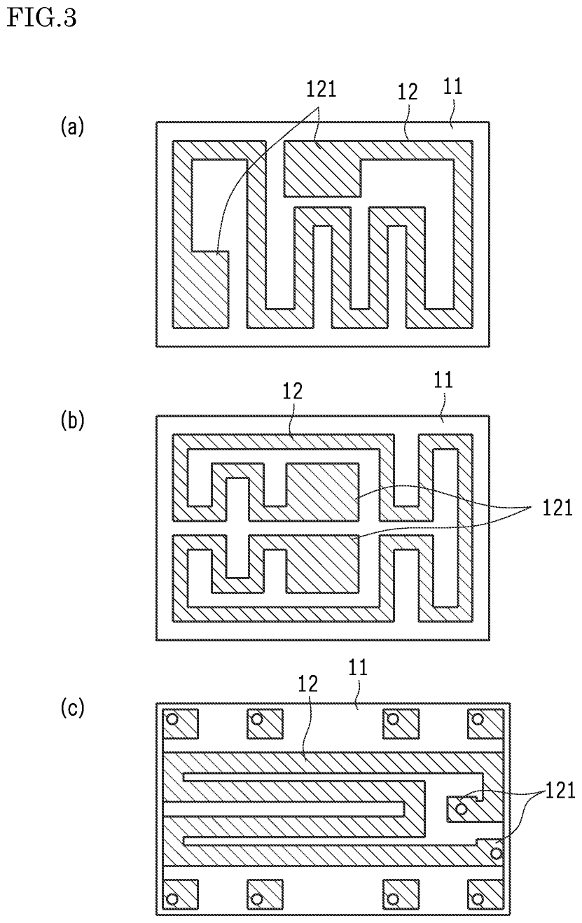

In thin-film heater 10, the pattern of the metal wiring 12 is not particularly limited and may be optionally selected (see examples in FIGS. 3(a)-3(c)). For example, in a case where positions of the electrode terminals 121 in the metal wiring 12 depend on design conditions or other like factors for an OCXO, the metal wiring 12 may be patterned such that heat generation in a heat-generating area of the thin-film heater 10 can be as uniform as possible. Further in the thin-film heater 10, the insulated substrate 11 is not necessarily exclusive for the heater, but may also be used for a printed circuit board (PCB), etc. In other words, metal wiring and electrode terminals other than the metal wiring 12 may be formed on the insulated substrate 11 (see FIG. 3(c)).

### Embodiment 2

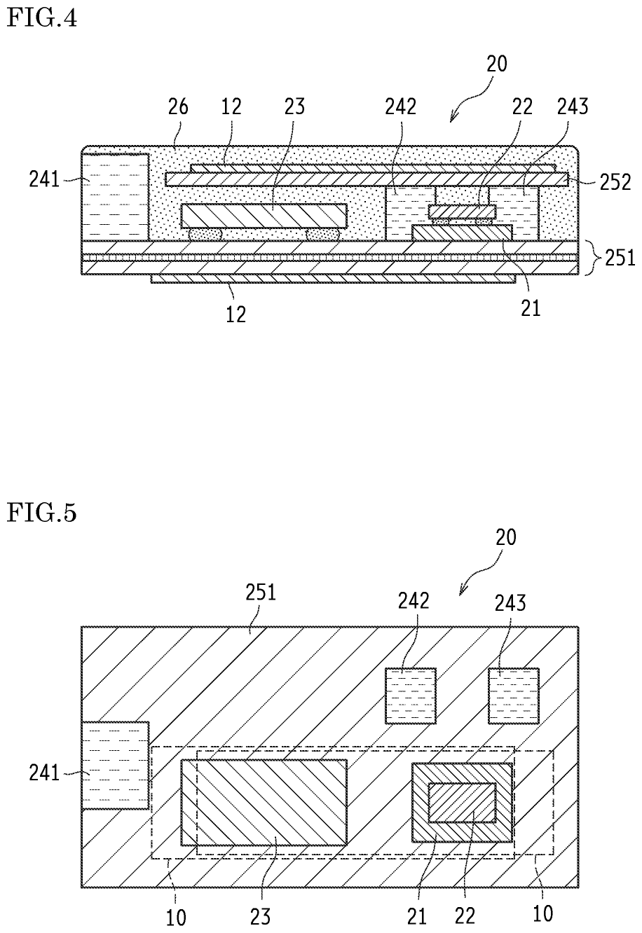

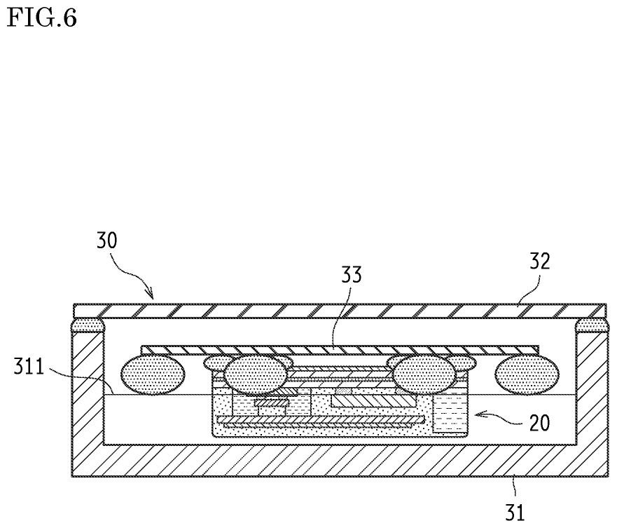

As described above, Embodiment 1 relates to the thin-film heater 10 that is meant for application to an OCXO. Embodiment 2, to be described below with reference to FIGS. 4 to 6, relates to a structure of an OCXO suitable for using the thin-film heater 10. FIG. 4 is a cross-sectional view showing a structural example of a core 20 of an OCXO 30 using the thin-film heaters 10. FIG. 5 is a plan view showing the structural example of the core 20. FIG. 6 is a cross-sectional view of the OCXO 30, with the core 20 on-board.

The core 20 contains, in a package, a crystal resonator (a resonator) 21, an oscillator IC 22, a heater IC 23, chip capacitors 241-243, and other various electronic components used for the OCXO 30. These components are arranged on a crystal substrate 251 and encapsulated in a sealing resin 26. The core 20 adjusts temperatures of the electric components, particularly those having significant temperature characteristics such as the crystal resonator 21, the oscillator IC 22, and the heater IC 23, and can thereby stabilize the oscillation frequency.

Although the type of crystal resonator 21 is not particularly limited, a device having a sandwich structure is suitable because it is easily made thinner. The sandwich-structure device is composed of first and second sealing members made of glass or quartz, and a piezoelectric vibration plate made of, for example, quartz. Drive electrodes are provided on both main surfaces of the piezoelectric vibration plate. The first and second sealing members are stacked on and joined with each other via the piezoelectric vibration plate.

The oscillator IC 22 is combined with the crystal resonator 21 to constitute a crystal oscillator (an oscillator). The heater IC 23 adjusts the temperature of the core 20 and controls current to the thin-film heaters 10 used in the core 20. In the present invention, the heater IC 23 itself may function as a heating element. In other words, the heater IC 23 may have a structure that integrates a heating element (a heat source other than the thin-film heaters 10), a circuit for controlling temperatures of heating elements (including the thin-film heaters 10) (a circuit for electric current control), and a temperature sensor for detecting the temperature inside the core 20. The heater IC 23 controls and keeps the temperature of the core 20 substantially constant, and this temperature adjustment contributes to stabilization of the oscillation frequency of the OCXO 30.

The core 20 further includes two crystal substrates 251 and 252. The metal wiring 12 is formed on both of the crystal substrates 251 and 252, and used as the thin-film heaters 10. Note that FIG. 5 omits the crystal substrate 252 and the metal wiring 12, and indicates heat-generating areas of the thin-film heaters 10 by dashed frames. Additionally, the crystal substrate 251 in the present invention, shown in FIG. 4 as a stacked substrate composed of two crystal plates, is not limited thereto and may be a single-layer substrate composed of a single crystal plate.

In the core 20, the crystal resonator 21, the oscillator IC 22, and the heater IC 23 are arranged between the crystal substrates 251 and 252, namely, between the thin-film heater 10 formed on the crystal substrate 251 and the thin-film heater 10 formed on the crystal substrate 252. The thus configured core 20 can adjust temperatures of the crystal resonator 21, the oscillator IC 22, and the heater IC 23 with high precision (at uniform temperatures), in a space defined between the two thin-film heaters 10 (a temperature adjustment space).

Regarding the arrangement of the components subjected to temperature adjustment, as viewed in plan view, it is not always necessary to fit the entirety of such components within the area of the temperature adjustment space. In the example of FIG. 5, a part of the heater IC 23 extends beyond the area of the temperature adjustment space, but the most part of the heater IC 23 lies within the area of the temperature adjustment space. This arrangement still ensures sufficient temperature adjustment for the heater IC 23.

Referring to the example of FIGS. 4 and 5, the components having low temperature characteristics, i.e. the chip capacitors 241-243, are arranged outside the area of the temperature adjustment space. In the present invention, however, the arrangement of the components having low temperature characteristics is not limited to this example. In fact, there is no particular problem in arranging those components within the area of the temperature adjustment space.

FIG. 6 shows a structure of the OCXO 30 that is composed of a housing 31 made of ceramics or the like and accommodating the core 20 inside, and a lid 32 sealing the housing 31. In the example of FIG. 6, the housing 31 has an internal step 311 conforming to the arrangement of connection terminals (not shown), and the core 20 is connected via an interposer 33 to the connection terminals formed on the step 311. This structure is suitable for reducing the thickness of the OCXO 30, but the arrangement of the core 20 and the manner of connecting the core 20 inside the housing 31 are not particularly limited in the present invention.

For OCXOs using the thin-film heaters 10, the core structure is not limited to the one shown in FIGS. 4 to 6, and can be modified in various manners. For example, regarding the core 20 shown in FIG. 4, the heater IC 23 is not stacked on the crystal resonator 21 and the oscillator IC 22 but arranged on a separate area on the crystal substrate 251. Instead, all of the heater IC 23, the crystal resonator 21, and the oscillator IC 22 may be stacked on each other on the crystal substrate 251. Further alternatively, while the core 20 shown in FIG. 4 uses two thin-film heaters 10, the number of thin-film heaters 10 is not particularly limited, and use of at least one thin-film heater 10 is sufficient.

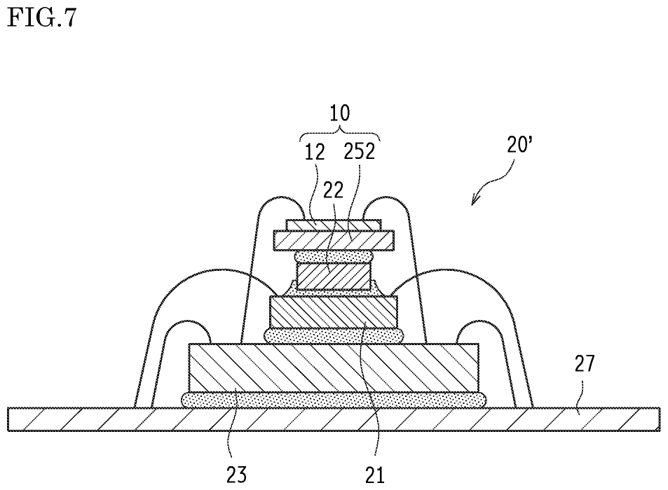

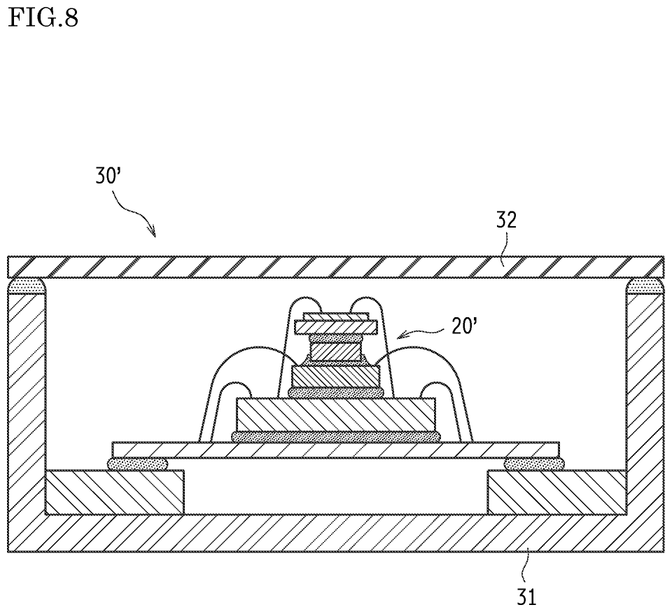

For example, FIG. 7 is a cross-sectional view showing a core 20′, which is a modified example of the core of an OCXO using the thin-film heater 10. FIG. 8 is a cross-sectional view of an OCXO 30′, with the core 20′ on-board. In FIG. 7, the crystal substrate 252 and the metal wiring 12 correspond to the thin-film heater 10.

The core 20′ shown in FIG. 7 has a four-layer structure (a stacked structure) in which the heater IC 23, the crystal resonator 21, the oscillator IC 22, and the thin-film heater 10 are stacked on a flat plate-like core substrate 27 sequentially from the bottom (from the core substrate 27 side). The core substrate 27 can be made of, for example, a crystal substrate or a resin substrate such as a polyimide resin substrate. As viewed in plan view, the areas of the heater IC 23, the crystal resonator 21, and the oscillator IC 22 decrease gradually from the bottom to the top.

Also as viewed in plan view, the thin-film heater 10 has such a dimension (both lengthwise and widthwise) as to cover at least the entirety of the oscillator IC 22, which is preferable in terms of heat conduction. The various electronic components in the core 20′ are not encapsulated in a sealing resin, but may be encapsulated in a sealing resin, depending on the sealing atmosphere.

In the core 20′, the heater IC 23 and the crystal resonator 21 are wire bonded to connection terminals formed on the top surface of the core substrate 27. The oscillator IC 22 is flip-chip bonded or otherwise connected to the crystal resonator 21. Preferably, the thin-film heater 10 is adhesively bonded to the top surface of the oscillator

IC 22, and is wire bonded to the heater IC 23.

The OCXO 30′ shown in FIG. 8 has a structure similar to the OCXO 30 shown in FIG. 6. The OCXO 30′ is composed of the housing 31 made of ceramics or the like and accommodating the core 20′ inside, and the lid 32 sealing the housing 31. In the OCXO 30′, connection terminals formed on the bottom surface of the core 20′ (namely, the bottom surface of the core substrate 27) are connected to connection terminals formed inside the housing 31 via a conductive adhesive.

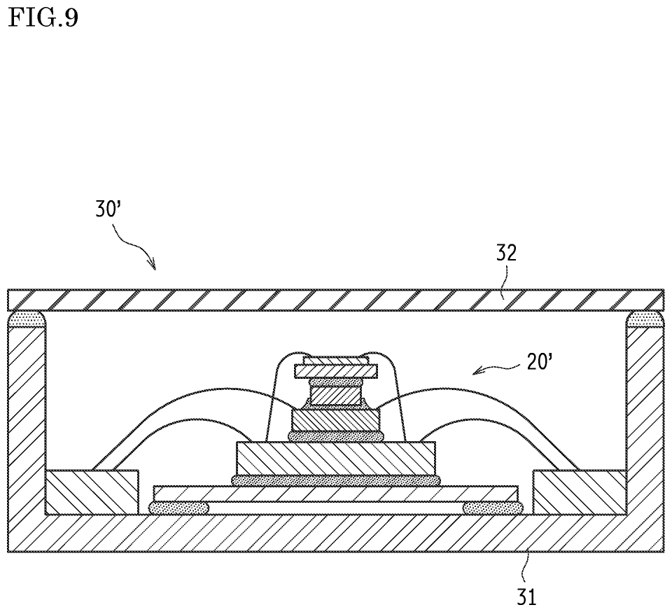

FIG. 9 shows another connection configuration of the OCXO 30′. As illustrated, the bottom surface of the core substrate 27 may be bonded via an adhesive agent to the inner lower surface of a recess in the housing 31, and the heater IC 23 and the crystal resonator 21 may be wire bonded to connection terminals formed on a top surface of a shoulder inside the housing 31. In this configuration, the thin-film heater 10 may be connected, via wires, either to terminals formed on the top surface of the core substrate 27 or to the connection terminals formed on the top surface of the shoulder inside the housing 31.

The embodiments disclosed herein are considered in all respects as illustrative and should not be any basis of restrictive interpretation. The scope of the present invention is therefore indicated by the appended claims rather than by the foregoing embodiments alone. The technical scope of the present invention is intended to embrace all variations and modifications falling within the equivalency range of the appended claims.

### REFERENCE SIGNS LIST

10 thin-film heater

11 insulated substrate

12 metal wiring

12A heat-generating layer

12B underlayer

121 electrode terminal

20, 20′ core

21 crystal resonator (resonator)

22 oscillator IC

23 heater IC

241-243 chip capacitor

251, 252 crystal substrate

27 core substrate

30, 30′ OCXO

31 housing

32 lid

1. A thin-film heater comprising an insulated substrate and metal wiring patterned thereon to extend between both terminals of the metal wiring, wherein
the metal wiring has a resistance of 10Ω or less between the terminals, and
the metal wiring comprises a heat-generating layer made of a material that recrystallizes at a temperature of 200° C. or lower.

2. A thin-film heater comprising an insulated substrate and metal wiring patterned thereon to extend between both terminals of the metal wiring, wherein
the metal wiring has a resistance of 10Ω or less between the terminals, and
the metal wiring comprises a heat-generating layer formed as a recrystallized film.

3. The thin-film heater according to claim 1, wherein
a material for the heat-generating layer is selected from the group consisting of gold (Au), aluminum (Al), silver (Ag), and copper (Cu).

4. The thin-film heater according to claim 1, wherein
the insulated substrate comprises quartz or glass, and
the metal wiring comprises an underlayer formed between the insulated substrate and the heat-generating layer.

5. The thin-film heater according to claim 4, wherein
the heat-generating layer has a film thickness of 30 nm or more, and
the underlayer has a film thickness of 10 nm or less.

6. A method of producing a thin-film heater that comprises an insulated substrate and metal wiring patterned thereon to extend between both terminals of the metal wiring, the metal wiring comprising a heat-generating layer, wherein
the method comprises forming the heat-generating layer through depositing and patterning,
the depositing comprises using a material that recrystallizes at a temperature of 200° C. or lower, preheating the insulated substrate to 200° C. or higher, and depositing a metal film on the preheated insulated substrate by a vacuum vapor deposition method, and
the patterning comprises patterning, by etching, the metal film deposited in the depositing.

7. The method of producing a thin-film heater according to claim 6, wherein
the material for the heat-generating layer is selected from the group consisting of gold (Au), aluminum (Al), silver (Ag), and copper (Cu).

8. The method of producing a thin-film heater according to claim 6, wherein
the insulated substrate comprises quartz or glass, and
the metal wiring comprises an underlayer formed between the insulated substrate and the heat-generating layer.

9. The method of producing a thin-film heater according to claim 8, wherein
the heat-generating layer has a film thickness of 30 nm or more, and
the underlayer has a film thickness of 10 nm or less.

10. An oven-controlled piezoelectric oscillator comprising a heater, a resonator, an oscillator IC combined with the resonator to configure an oscillator, and a heater IC for controlling the heater, wherein
the heater at least comprises one or more thin-film heaters according to claim 1.

11. The oven-controlled piezoelectric oscillator according to claim 10, wherein
the heater comprises two of the one or more thin-film heaters,
the oven-controlled piezoelectric oscillator further comprises a core in which the resonator, the oscillator IC, and the heater IC are arranged in a temperature adjustment space defined between the two thin-film heaters, and
the core is hermetically encapsulated in an insulation package.

12. The oven-controlled piezoelectric oscillator according to claim 10, wherein
the oven-controlled piezoelectric oscillator further comprises a core in which the heater IC, the resonator, the oscillator IC, and the thin-film heater are stacked on a flat plate-like core substrate sequentially from a side of the core substrate, and
the core is hermetically encapsulated in an insulation package.
